(19) United States
(12) Patent Application Publication
(10) Pub. No.: US 2025/0019243 A1
(43) Pub. Date: Jan. 16, 2025

(54) METALLIC SINGLE-WALLED CARBON NANOTUBE HYBRID ASSEMBLIES AND SUPERSTRUCTURES

(71) Applicant: DUKE UNIVERSITY, Durham, NC (US)

(72) Inventors: Michael THERIEN, Durham, NC (US); Francesco MASTROCINQUE, Durham, NC (US); George BULLARD, Durham, NC (US); Animesh NAYAK, Durham, NC (US); Yusong BAI, Durham, NC (US)

(21) Appl. No.: 18/713,948

(22) PCT Filed: Nov. 29, 2022
(86) PCT No.: PCT/US2022/051258

§ 371 Date: May 28, 2024

Related U.S. Application Data
(60) Provisional application No. 63/283,757, filed on Nov. 29, 2021.

(51) Int. Cl. C01B 32/174; B82Y 30/00; B82Y 40/00; C01B 32/159; H01L 29/06

(52) U.S. Cl. CPC C01B 32/174; C01B 32/159; B82Y 30/00; B82Y 40/00; C01B 2202/02; C01B 2202/22; C01P 2006/40; C01P 2006/60; H01L 29/0669

(57) ABSTRACT

A metallic single-walled carbon nanotube (SWNT) hybrid assembly or superstructure includes a single walled carbon nanotube (SWNT) having a chiral index (n, m) where (n−m)/3 is an integer or 0; and an oligomer or polymer that single-chain wraps the metallic SWNT, wherein the oligomer or polymer is formed of repeat units, wherein each repeat unit has at least one charged functional group per 1-3 nm of oligomer or polymer length. The superstructure is suitable for optical, electro-optical, and spintronic-based device applications.

### CROSS REFERENCE TO RELATED APPLICATION(S)

This application claims the benefit of U.S. Provisional Patent Application Ser. No. 63/283,757, which was filed Nov. 29, 2021.

### GOVERNMENT SUPPORT

This invention was made with government support under Federal Grant No. FA9550-18-1-0222 awarded by the Air Force Office of Scientific Research (AFOSR). The U.S. Government has certain rights in this invention.

### BACKGROUND

There is an incontrovertible need for low dimension materials that can provide reliable, high-performance microelectronics. Single-walled carbon nanotubes (SWNTs) are one-dimensional materials that are ideal for microelectronic applications due in part to their unique optical and electronic attributes. SWNTs possess superior charge carrier mobilities when compared to conventional microelectronic materials such as Si and GaAs, and their π-conduction pathways are impervious to electromigration which is an increasing source of failure as device size decreases. Nanotube based technologies are hindered by the current standards of production, which yield heterogeneous distributions of SWNT diameters or chiralities. These irregular compositions of electronic structures often preclude their inclusion in practical applications such as field-effect transistors (FETs) or optical sensors. Many optical, electronic, and spintronic applications of SWNTs require either the synthesis or isolation of a single SWNT electronic structure.

### BRIEF SUMMARY

Metallic single-walled carbon nanotube (“m-SWNT” or “metallic SWNT”) hybrid assemblies and superstructures are described that can provide novel low-band gap materials that possess electronic structures distinct from conventional semiconducting single-walled carbon nanotubes (s-SWNTs). Such m-SWNT superstructures are suitable for optical, electro-optical, and spintronic-based device applications.

A superstructure is provided that includes a metallic single walled carbon nanotube (SWNT) having a chiral index (n, m) where (n−m)/3 is an integer or 0; and a conjugated oligomer or polymer that single-chain wraps a surface of the metallic SWNT at fixed helical pitch length. The conjugated oligomer or polymer is formed of repeat units, wherein each repeat unit has at least one charged functional group per 1-3 nm of oligomer or polymer length. The conjugated oligomer or polymer can be selected to control a band gap opening in the metallic SWNT.

A method of controlling band gap openings in metallic carbon nanotubes includes selecting an oligomer or polymer, wherein the oligomer or polymer is formed of repeat units, wherein each repeat unit has at least one charged functional group per 1-3 nm of oligomer or polymer length; dispersing metallic single walled carbon nanotubes (SWNTs) in a suspension, the metallic SWNTs having a chiral index (n, m) where (n−m)/3 is an integer or 0; and mixing an aqueous solution of the oligomer or polymer with the metallic SWNTs in the suspension to form superstructures having a desired band gap opening, each superstructure comprising a metallic SWNT of the metallic SWNTs and a conjugated oligomer or polymer of the selected oligomer or polymer that single-chain wraps about a surface of the metallic SWNT at fixed helical pitch length.

The method results in m-SWNTs that are helically wrapped in a single chain fashion by chiral semiconducting polymers (or oligomers). These assemblies provide robust organic and aqueous solvent soluble superstructures featuring exceptional electronic and morphological homogeneity.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIGS. 1A and 1B illustrate example chiralities of carbon nanotubes along with type of lattice vector.

FIGS. 2A-2I illustrate example binaphthalene (PBN)-based chiral semiconducting polymers that can be used.

FIG. 2J shows a chemical structure of an exemplary functional group, denoted as R.

FIGS. 3A and 3B show an illustrative example of a selected polymer and resulting wrapped metallic SWNT.

FIGS. 4A and 4B show chiroptical and potentiometric measurements of a wrapped metallic SWNT compared to the unwrapped metallic SWNT.

FIGS. 5A and 5B show Kelvin probe force microscopy (KPFM) measurements of surfactant encapsulated (11,11) SWNTs and polymer-wrapped metallic SWNTs, respectively.

FIG. 6 shows plots of FT-IR experiments comparing surfactant encapsulated (11, 11) SWNTs, polymer, and polymer-wrapped metallic SWNTs.

FIG. 7 shows exemplary Raman spectroscopic data.

FIGS. 8A and 8B show a representative metallic-SWNT and corresponding first Brillouin Zone of the pure metallic-SWNT and a polymer-wrapped metallic-SWNT, respectively.

FIG. 9 shows a field-effect transistor configuration that exploits both (11,11) SWNTs and polymer-wrapped S-PBN(b)-Ph₄-[(11,11) SWNTs].

FIG. 10 shows a plot of current to gate voltage for the transistors of FIG. 9.

### DETAILED DESCRIPTION

Metallic single-walled carbon nanotube (m-SWNT) hybrid assemblies and superstructures are described that can provide novel low-band gap materials that possess electronic structures distinct from conventional semiconducting single-walled carbon nanotubes (s-SWNTs). Such m-SWNT superstructures are suitable for optical, electro-optical, and spintronic-based device applications.

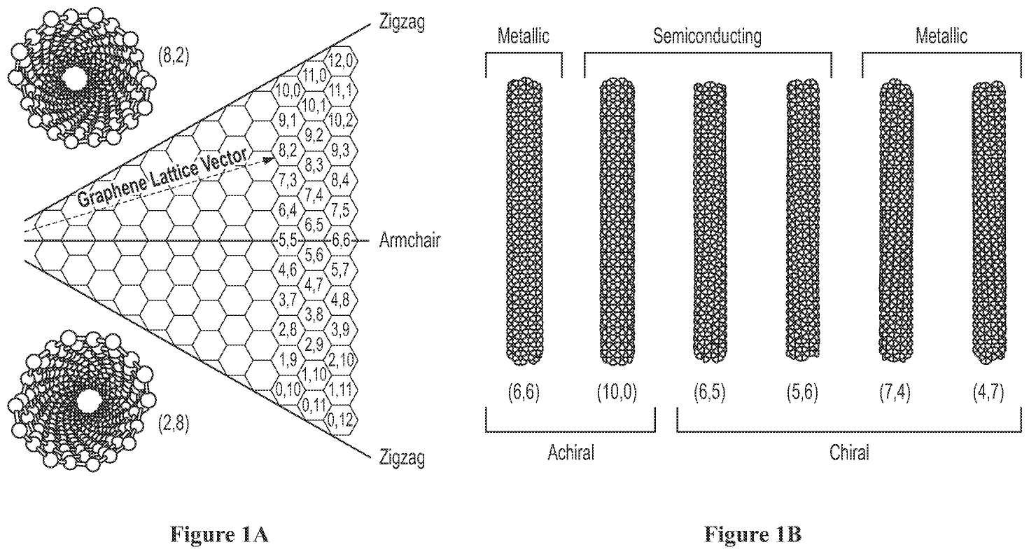

Single-walled carbon nanotube fabrication for semiconductor applications results in chiralities that are currently going to waste. “Chirality” in the context of nanotubes describes how the graphene sheet is rolled up, from zigzag to armchair. FIGS. 1A and 1B illustrate example chiralities of carbon nanotubes along with type of lattice vector. The (n, m) format indicates the chiral index of the SWNT, which describes the particular rolling configuration. Each SWNT chirality possesses a unique electronic structure and can be considered metallic or semiconducting. A metallic SWNT is one where (n−m)/3 is an integer or 0 and a semiconducting SWNT is one where (n−m)/3 is not 0 or an integer. The described methods for controlling band gap openings in metallic carbon nanotubes and compositions comprising same can take any SWNT where (n−m)/3 is an integer or 0 and generate a band gap suitable for optical, electro-optical, and spintronic-based device applications.

One potential way to introduce a low-energy band gap in metallic-SWNTs is to break the sublattice symmetry by exploiting interfacial electronic interactions between the SWNT sp² carbons with other conjugated structures, whereby certain regions of SWNT sp² carbons electronically mix with the other conjugated structure, while other regions do not. In such a manner, the equivalency of adjacent sites in the SWNT unit cell will be partially removed. Along these lines, theoretical work has predicted that tube-tube interactions in nanotube ropes/bundles could break the lattice symmetry and open a bandgap of ˜0.1 eV at the Fermi level for (10,10) metallic SWNTs.

Through the described chiral oligomer/polymer-wrapping methods, it is possible to break sublattice symmetry in a controllable manner via the morphologically uniform nature of the polymer-SWNT interactions. In particular, the nature of oligomer/polymer to SWNT electronic interactions may be tuned through control of the relative oligomer/polymer frontier orbital and the metallic-SWNT Fermi energy levels.

Chiral oligomer/polymer-wrapped SWNT suspensions can be prepared by slowly mixing an aqueous solution of a selected oligomer/polymer with presuspended, surfactant-coated carbon nanotube suspensions. Unbound oligomers/polymers can be removed, for example, via gel permeation chromatography (GPC). Accordingly, a method of controlling band gap openings in metallic carbon nanotubes can include dispersing metallic SWNTs in a suspension, the metallic SWNTs having a chiral index (n, m) where (n−m)/3 is an integer or 0; and mixing an aqueous solution of a selected oligomer or polymer with the metallic SWNTs in the suspension to form superstructures having a desired band gap opening, each superstructure including a metallic SWNT of the metallic SWNTs and a conjugated oligomer or polymer of the selected oligomer or polymer that single-chain wraps about a surface of the metallic SWNT at fixed helical pitch length.

In various implementations, the metallic SWNTs used to form the superstructures can be selected from metallic SWNTs having a chiral index of (16,1), (16,4), (16,7), (16,10), (16,13), (16,16), (15,0), (15,3), (15,6), (15,9), (15,12), (15,15), (14,2), (14,5), (14,8), (14,11), (14,14), (13,1), (13,4), (13,7), (13,10), (13,13), (12,0), (12,3), (12,6), (12,9), (12,12), (11,2), (11,5), (11,8), (11,11), (10,1), (10,4), (10,7), (10,10), (9,0), (9,3), (9,6), (9,9), (8,2), (8,5), (8,8), (7,1), (7,4), (7,7), (6,0), (6,3), (6,6), (5,2), (5,5), (4,1), (4,4), (3,0), (3,3), (2,2), or (1,1). In certain implementations, the chiral index of the metallic SWNTs used to form the superstructures are one or more of (14,5), (13,7), (12,12), (12,6), (11,11), (10,10), (9,9), (9,6), (9,3), (8,8), (8,5), (8,2), (7,4), (6,6), or (5,5).

An oligomer/polymer used for the described superstructures is one that exhibits single-chain wrapping and the ability to wrap a nanotube lattice at a fixed helical pitch length. The selected oligomer/polymer is selected from oligomers or polymers having repeat units where each repeat unit has at least one charged functional group per 1-3 nm, for example per 1.5 nm of oligomer or polymer length.

In some cases, the charged functional group is an alkoxy sulfonic acid. The repeat units of the conjugated oligomer or polymer can include a plurality of aryleneethynylene units in which the at least one charged functional group is incorporated at least once every 1-3 nm of oligomer or polymer length.

In some cases, each aryleneethynylene unit of the plurality of aryleneethynylene units forming the conjugated oligomer or polymer contain 10 or fewer carbon fused aromatic ring systems. In some cases, an aryleneethynylene unit of the plurality of aryleneethynylene units contains an aromatic heterocycle. In some cases, an aryleneethynylene unit of the plurality of aryleneethynylene units contains a conjugated moiety that enables modulation of the oligomer or polymer's oxidation or reduction potential. The conjugated moiety can be, for example, rylene, porphyrin, aniline, thiophene, indole, quinone, carbazole, pyridine, pyrrole, furan, oxazole, indole, purine, benzofuran, benzothiophene, thiazole, pyrazole, quinoline, benzo[c][1,2,5]thiadiazole, [1,2,5]thiadiazolo[3,4-g]quinoxaline benzo[1,2-c:4,5-c′]bis([1,2,5]thiadiazole), ferrocene, or a macrocycle.

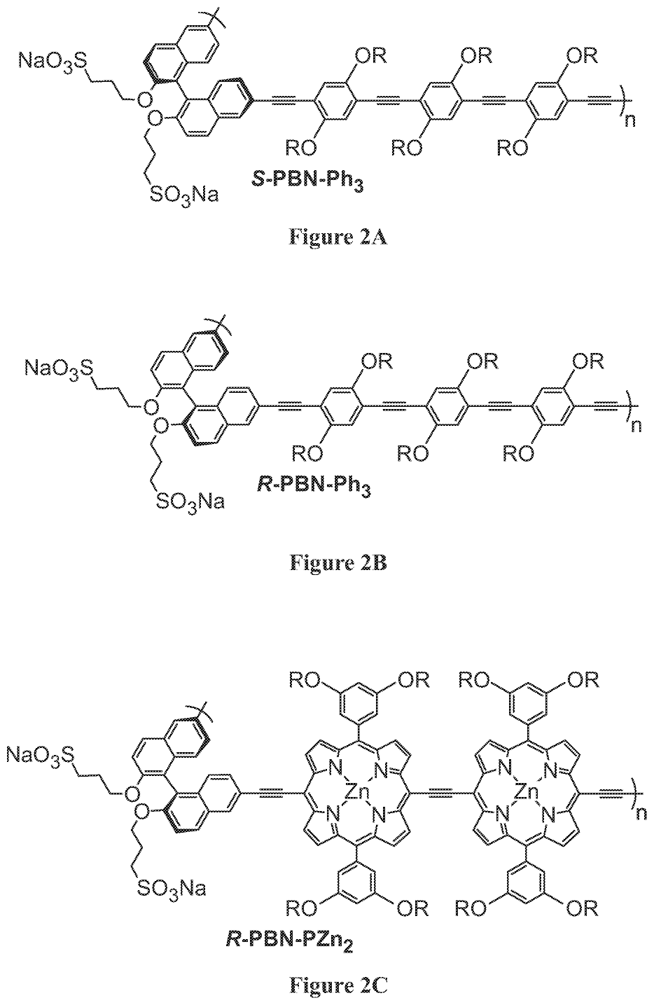

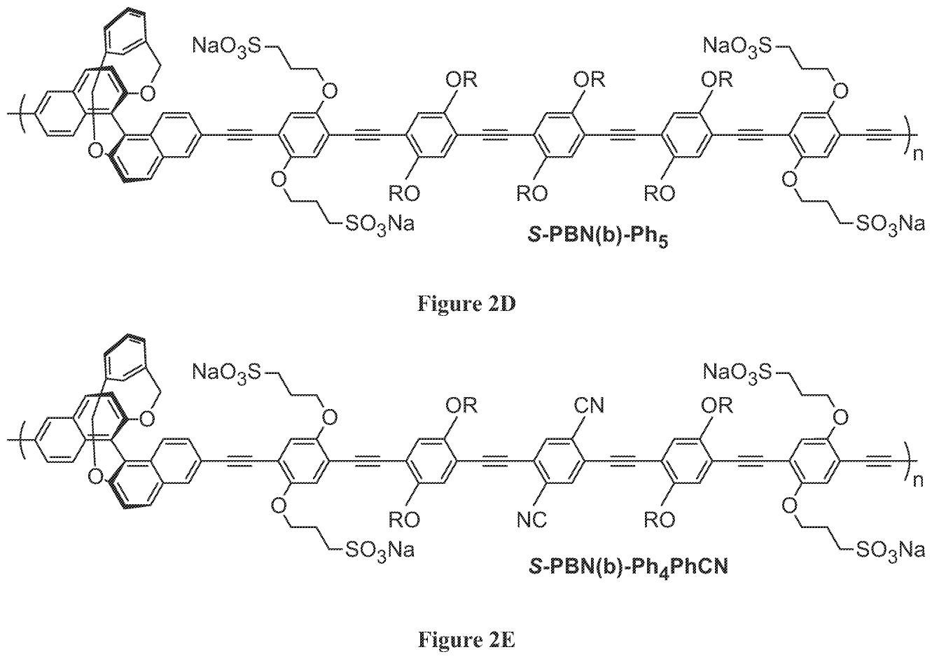

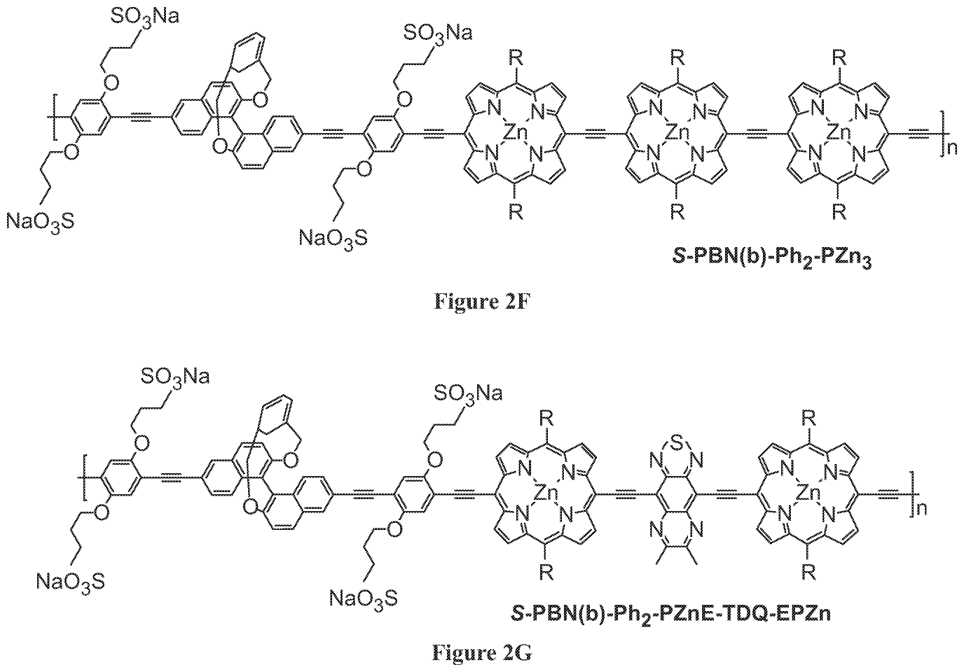

The repeat units of the conjugated oligomer or polymer can possess a moiety that directs the conjugated oligomer or polymer to helically wrap the metallic-SWNT surface in a left- or right-handed helical fashion. In some cases, the repeat units feature a R- or S-PBN-based unit as the oligomer/polymer chiral directing moiety. For example, any of the polymers shown herein may be used as the selected polymer (e.g., in FIGS. 2A-2I and 3A described below).

FIGS. 2A-2I illustrate example binaphthalene (PBN)-based chiral semiconducting polymers that can be used; and FIG. 2J shows a chemical structure of an exemplary functional group, denoted as R. FIG. 2A shows S-PBN-Ph₃, FIG. 2B shows R-PBN-Ph₃, FIG. 2C shows R-PBN-PZn₂, FIG. 2D shows S-PBN(b)-Ph₅, FIG. 2E shows S-PBN(b)-Ph₄PhCN, FIG. 2F shows S-PBN(b)-Ph₂PZn₃, FIG. 2G shows S-PBN(b)-Ph₂-PZnE-TDQ-EPZn, FIG. 2H shows S-PBN(b)-Ph₂PZn₂, and FIG. 2I shows S-PBN-Ph₄PDI. The R- and S-PBN-based aryleneethynylene polymers give rise to single-handed helical wrapping of single-walled carbon nanotubes. Of course, other oligomers and polymers with other chiral directing groups may be used. By using a variety of compositions that involve a polymer repeat unit that has at least one charged functional group per 1-3 nm of polymer length (e.g., at least one charge per six aromatic units), an appropriate facial interaction and particular directionality of the single-chain wrapping (e.g., left-handed or right-handed wrapping) can be achieved.

FIGS. 3A and 3B show an illustrative example of a selected polymer and resulting wrapped metallic SWNT. Wrapping metallic (11,11) SWNTs with the aryleneethynylene polymer S-PBN(b)-Ph₄ shown in FIG. 3A produces S-PBN(b)-Ph₄-[(11,11) SWNT] superstructures as reflected in FIG. 3B.

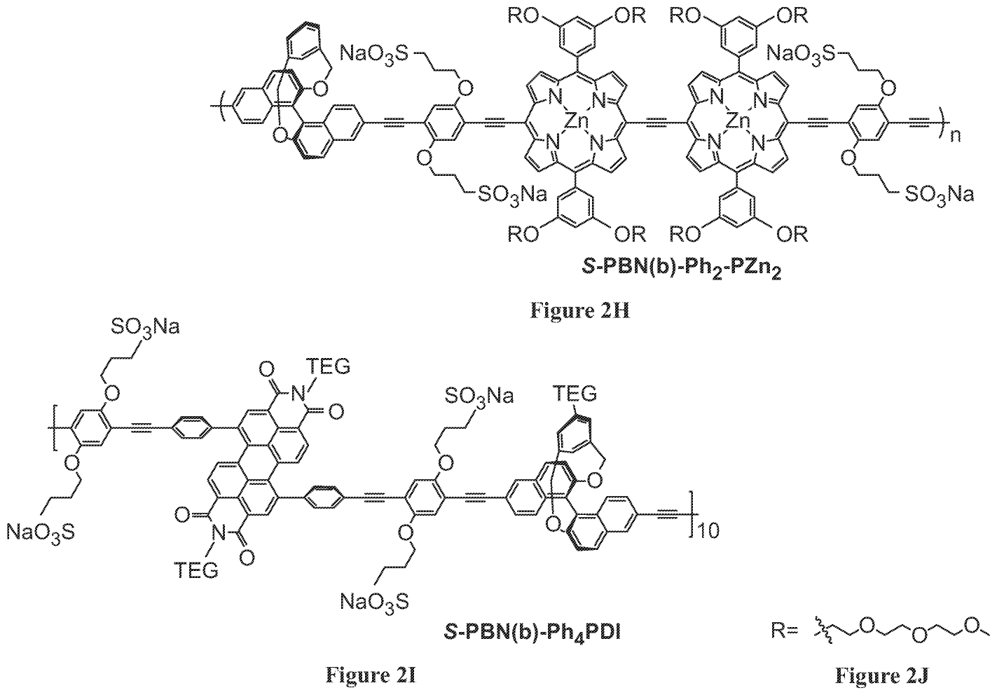

FIGS. 4A and 4B show chiroptical and potentiometric measurements of a wrapped metallic SWNT compared to the unwrapped metallic SWNT. As shown in FIG. 4A, S-PBN(b)-Ph₄-[(11,11) SWNTs] (such as illustrated in FIG. 3B) display absorption of circularly polarized light within the (11,11) metallic-SWNT M₁₁ transition manifold (550-750 nm), whereas achiral (11,11) SWNTs displays no such circular dichroism (CD) signal. These data provide chiro-optic confirmation of symmetry breaking, indicating that semiconducting polymer wrapping drives displacement of metallic-SWNT excited-state electron density along a helically chiral path. Polymer dewrapping gives rise to (11,11) SWNTs that display no CD response. As shown in FIG. 4B, cyclic voltametric data acquired for the S-PBN(b)-Ph₄-[(11,11) SWNTs] indicate a difference in onset potential of ˜0.28 eV.

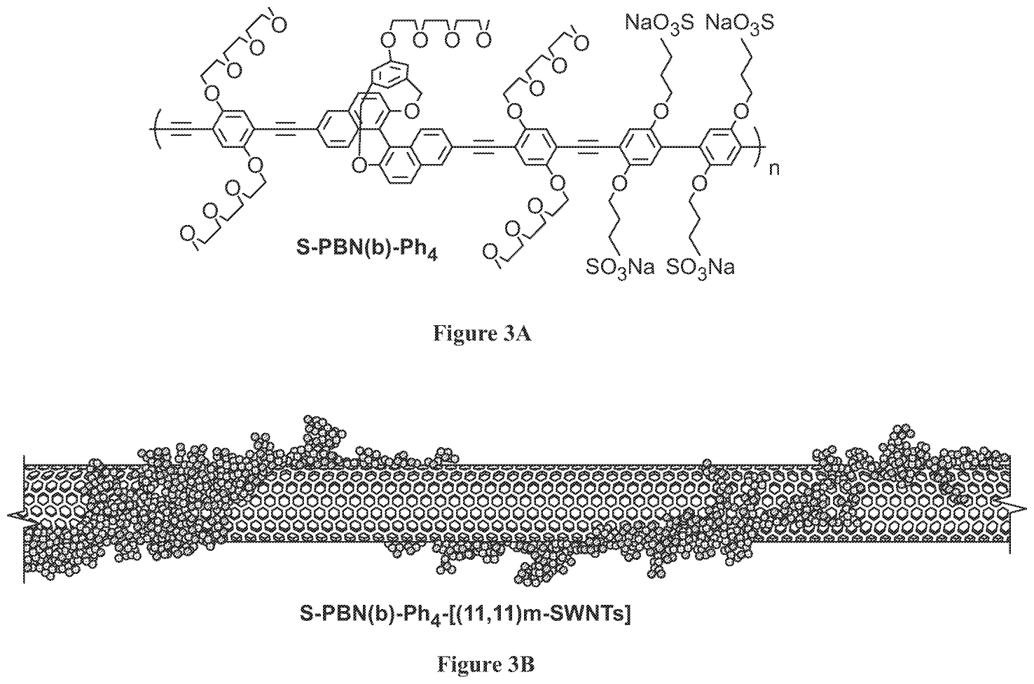

FIGS. 5A and 5B show Kelvin probe force microscopy (KPFM) measurements of surfactant encapsulated (11,11) SWNTs and polymer-wrapped metallic SWNTs, respectively. Referring to FIG. 5A, two surfactant encapsulated metallic SWNTs were evaluated (profile 1 and profile 2) and have a resultant work function of ˜5.68 eV. Referring to FIG. 5B, a polymer-wrapped metallic SWNT was selected for evaluation (profile 1) and has a resultant work function of ˜ 5.35 eV. As can be seen, there is a ˜0.3 eV change in the work function (W_{F}) of S-PBN(b)-Ph₄-[(11,11) SWNTs] (W_{F}=5.36 eV) relative to pristine (11,11) SWNTs (W_{F}=5.68 eV).

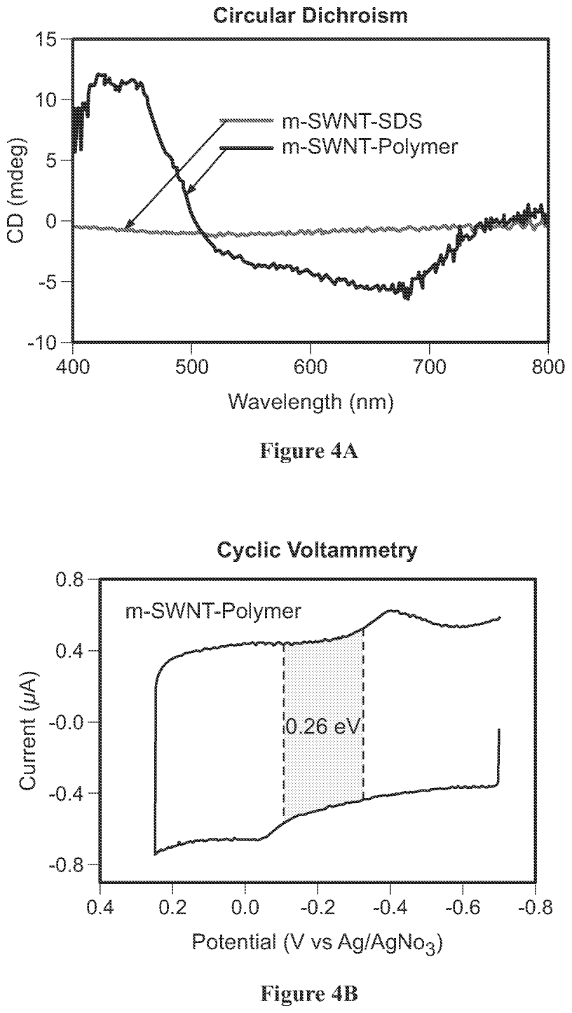

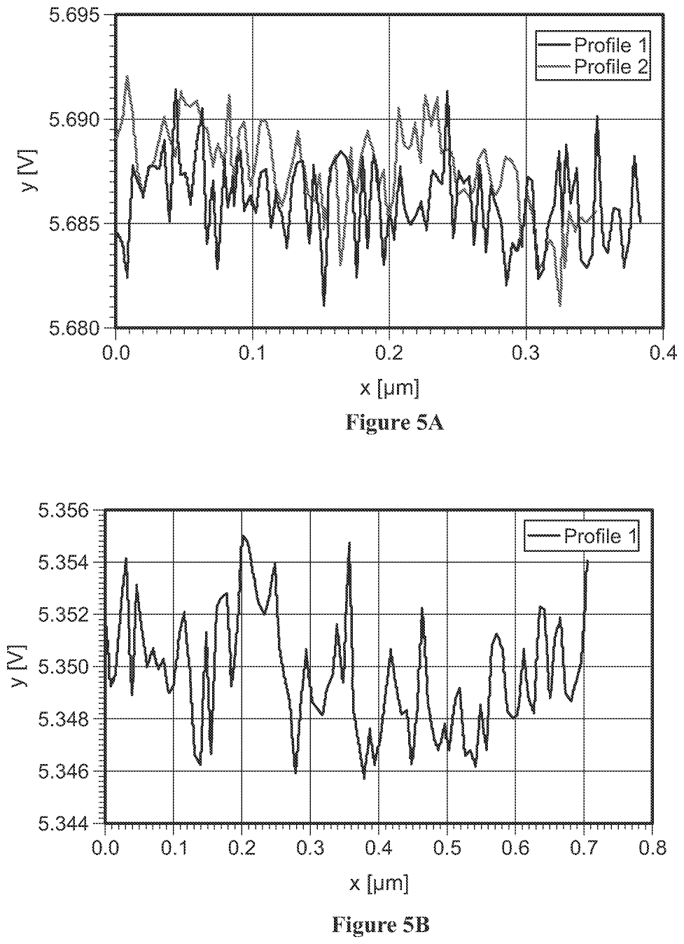

Congruent with the KPFM data that point to band gap opening, FT-IR experiments, as shown in FIG. 6, reveal a new optical signature at 2500 cm⁻¹ (˜0.3 eV) for the S-PBN(b)-Ph₄-[(11,11)-SWNTs] that is absent for both surfactant-dispersed (11,11) SWNTs and the S-PBN(b)-Ph₄ polymer alone. In addition, the S-PBN(b)-Ph₄-[(11,11) SWNT] Raman spectrum shown in FIG. 7 reflects G mode signatures (−G and +G signatures) strongly reminiscent of semiconducting nanotubes under 633 nm laser excitation.

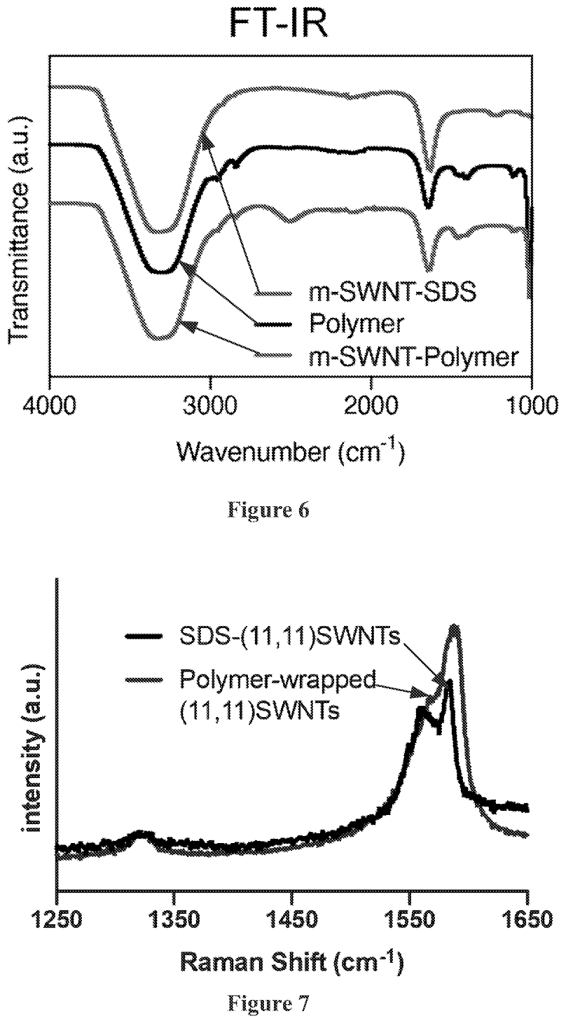

An effect that emerges from “rolling up graphene” to form a SWNT is the imposition of a periodic boundary condition: unlike graphene, SWNTs possess a series of allowed wave vectors (\vec{k}) in reciprocal space (K-space), known as quantization lines. It has been found that single-chain metallic-SWNT wrapping with rigid semiconducting polymers at constant helical pitch length provides a mechanism to shift allowed metallic-SWNT wavevectors off of the K and K′ points, as shown in FIGS. 8A and 8B, which can controllably open low-energy band gaps. Disruption of the highly symmetric electronic structure of (11,11) SWNTs through polymer wrapping shifts the allowed wave vectors away from the K and K′ Dirac points in reciprocal space, resulting in a metallic to semiconducting phase transition in these metallic-SWNT assemblies.

Referring to FIG. 8A, if the quantization lines run straight through the K or K′ points, the E(k) dispersion close to E_{F} is linear, giving rise to zero band gap, i.e., the band structure for metallic SWNTs. Referring to FIG. 8B, if the quantization lines bypass the K or K′ points with a separation of |Δκ|, the E(k) dispersion is represented by a pair of parabolas, corresponding to a band gap E_{g}, representing the band structure for semiconducting SWNTs. As shown herein, rigid, semiconducting polymers that helically wrap the metallic-SWNT surface at fixed pitch length can drive symmetry breaking, providing a new mechanism to evolve low energy band gaps by design and novel short-wave IR (SWIR) materials.

Dipole-dipole interactions give rise to new allowed and forbidden exciton states which depend on the size and orientation of the two dipole vectors. SWNT-polymer electronic interactions that involve metallic-SWNTs and highly conjugated aryleneethynylene polymers, such as shown in FIGS. 2A-2I, that helically wrap the nanotube surface at fixed periodicity in a single chain fashion will result in new allowed and forbidden transitions that differ from those of the parent m-SWNT and polymer. Indeed, results shown herein indicate that symmetry breaking of the SWNT electronic structure is accomplished through chiral single-chain helical polymer wrapping at a fixed pitch length that give rise to newly allowed low energy electronic transitions (˜300 meV; 2400 cm⁻¹; 4167 nm). These noncovalently wrapped polymer/m-SWNT hybrid assemblies do not introduce defects and therefore are practical for applications leveraging electronically homogeneous nanotubes that require high reproducibility, or for devices where band gap magnitudes are tuned on the fly through modulation of electrical or optical fields.

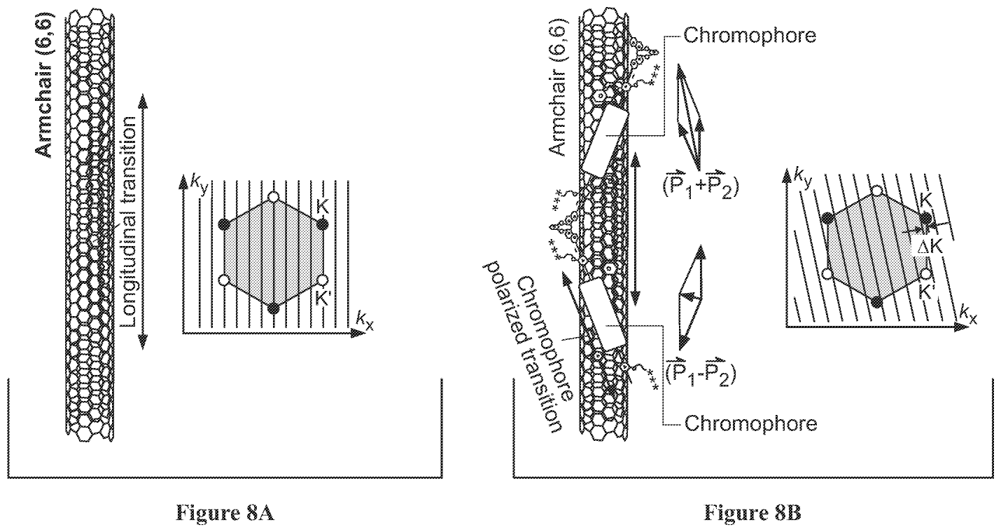

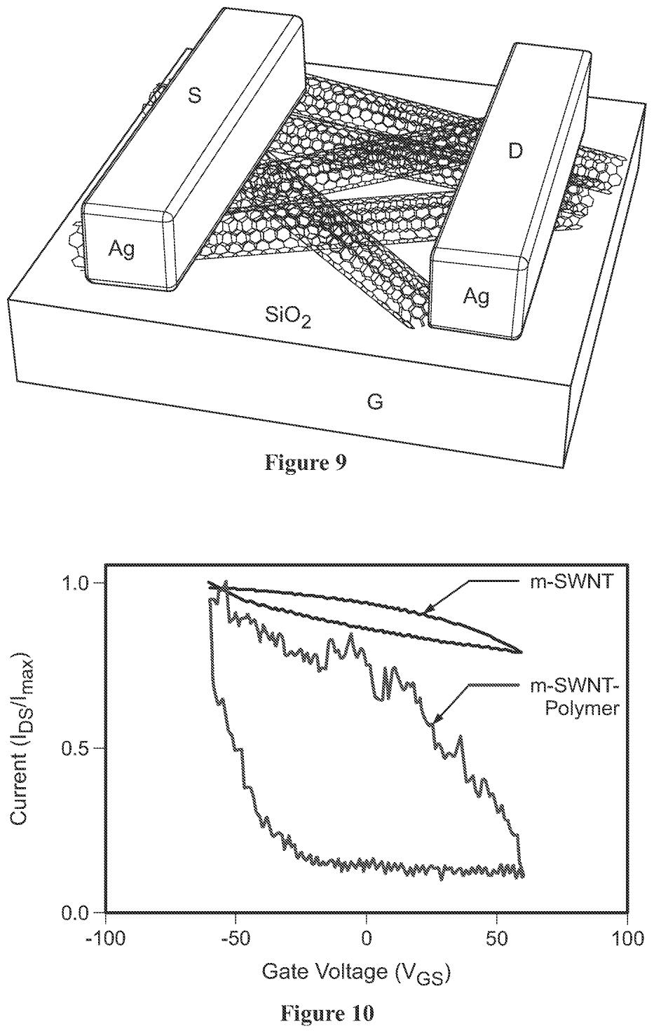

Field-effect transistors were fabricated using both (11,11) SWNTs and polymer-wrapped S-PBN(b)-Ph₄-[(11,11) SWNTs] as the channel material. FIG. 9 shows a field-effect transistor configuration that exploits both (11,11) SWNTs and polymer-wrapped S-PBN(b)-Ph₄-[(11,11) SWNTs]. Bottom gated field-effect transistors were fabricated using the metallic SWNT polymer superstructure of the example above. FIG. 10 shows a plot of current to gate voltage for the transistors of FIG. 9. As shown in FIG. 10, the devices made with S-PBN(b)-Ph₄-[(11,11) SWNTs] (m-SWNT-Polymer) displayed an order of magnitude larger normalized current on/off ratios (Iₒₙ/I_{off}=1.0) and a significant decrease in current (10⁻⁹ μA) relative to the (11,11) SWNT devices (m-SWNT Iₒₙ/I_{off}=0.1; current=10⁻⁶ μA).

For these potentiometric, Kelvin probe, optical, and device experiments, S-PBN(b)-Ph₄ polymer dewrapping gives rise to responses identical to those determined for pristine metallic-SWNTs. Accordingly, it is possible to controllably open low-energy band gaps in metallic SWNTs.

Opening metallic-SWNT band gaps using chiral, ionic semiconducting polymers that helically wrap the nanotube surface at constant morphology and rigorously fixed chirality provides new types of custom quantum detectors that detect short wavelength infrared radiation (0.9 to 2.5 μm). These “bandgap by design” approaches enable organic/nanomaterial hybrid compositions having unique detection capabilities between 2.0-2.5 μm, thereby providing selective detector and sensor elements that cannot be realized or replicated with established inorganic semiconductors. These hybrid organic nanomaterials not only open new avenues to implement detection flexibility, high resolution, and low voltage operation cost into device design: as most inorganic semiconductors require cryogenic cooling to operate beyond 2 μm, this capability addresses a key challenge for low band gap detector elements as those based on polymer-wrapped m-SWNT superstructures can be fabricated at low cost and have the flexibility to be utilized in a wide variety of environments.

“About” is used to provide flexibility to a numerical range endpoint by providing that a given value may be “slightly above” or “slightly below” the endpoint without affecting the desired result.

Recitation of ranges of values herein are merely intended to serve as a shorthand method of referring individually to each separate value falling within the range, unless otherwise indicated herein, and each separate value is incorporated into the specification as if it were individually recited herein. For example, if a concentration range is stated as 1% to 50%, it is intended that values such as 2% to 40%, 10% to 30%, or 1% to 3%, etc., are expressly enumerated in this specification. These are only examples of what is specifically intended, and all possible combinations of numerical values between and including the lowest value and the highest value enumerated are to be considered to be expressly stated in this disclosure.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

1. A superstructure comprising:
a metallic single walled carbon nanotube (SWNT) having a chiral index (n, m) where (n−m)/3 is an integer or 0; and
a conjugated oligomer or polymer that single-chain wraps a surface of the metallic SWNT at fixed helical pitch length, wherein the conjugated oligomer or polymer is formed of repeat units, wherein each repeat unit has at least one charged functional group per 1-3 nm of oligomer or polymer length.

2. The superstructure of claim 1, wherein the repeat units of the conjugated oligomer or polymer comprise a plurality of aryleneethynylene units in which the at least one charged functional group is incorporated at least once every 1-3 nm of oligomer or polymer length.

3. The superstructure of claim 2, wherein each aryleneethynylene unit of the plurality of aryleneethynylene units contain 10 or fewer carbon fused aromatic ring systems.

4. The superstructure of claim 2, wherein an aryleneethynylene unit of the plurality of aryleneethynylene units contains an aromatic heterocycle.

5. The superstructure of claim 2, wherein an aryleneethynylene unit of the plurality of aryleneethynylene units contains a conjugated moiety that enables modulation of the oligomer or polymer's oxidation or reduction potential.

6. The superstructure of claim 5, wherein the conjugated moiety is rylene, porphyrin, aniline, thiophene, indole, quinone, carbazole, pyridine, pyrrole, furan, oxazole, indole, purine, benzofuran, benzothiophene, thiazole, pyrazole, quinoline, benzo[c][1,2,5]thiadiazole, [1,2,5]thiadiazolo[3,4-g]quinoxaline benzo[1,2-c:4,5-c′]bis([1,2,5]thiadiazole), ferrocene, or a macrocycle.

7. The superstructure of claim 2, wherein the charged functional group is an alkoxy sulfonic acid.

8. The superstructure of claim 1, wherein the repeat units of the conjugated oligomer or polymer possess a moiety that directs the conjugated oligomer or polymer to helically wrap the surface of the metallic SWNT in a left- or right-handed helical fashion.

9. The superstructure of claim 8, wherein the repeat units feature a R- or S-binaphthalene (PBN)-based unit as the moiety that directs the conjugated oligomer or polymer to helically wrap the surface of the metallic SWNT in the left- or right-handed helical fashion.

10. (canceled)

11. The superstructure of claim 1, wherein the conjugated oligomer or polymer is S-PBN-Ph₃, R-PBN-Ph₃, R-PBN-PZn₂, S-PBN(b)-Ph₅, S-PBN(b)-Ph₄PhCN, S-PBN(b)-Ph₂PZn₃, S-PBN(b)-Ph₂-PZnE-TDQ-EPZn, S-PBN(b)-Ph₂PZn₂, S-PBN-Ph₄PDI, or S-PBN(b)-Ph₄.

12. The superstructure of claim 1, wherein the metallic SWNT has a chiral index of (11,11).

13. The superstructure of claim 1, wherein the metallic SWNT has a chiral index of (16,1), (16,4), (16,7), (16,10), (16,13), (16,16), (15,0), (15,3), (15,6), (15,9), (15,12), (15,15), (14,2), (14,5), (14,8), (14,11), (14,14), (13,1), (13,4), (13,7), (13,10), (13,13), (12,0), (12,3), (12,6), (12,9), (12,12), (11,2), (11,5), (11,8), (11,11), (10,1), (10,4), (10,7), (10,10), (9,0), (9,3), (9,6), (9,9), (8,2), (8,5), (8,8), (7,1), (7,4), (7,7), (6,0), (6,3), (6,6), (5,2), (5,5), (4,1), (4,4), (3,0), (3,3), (2,2), or (1,1).

14. (canceled)

15. A field effect transistor having a channel comprising the superstructure of claim 1.

16. A method of controlling band gap openings in metallic carbon nanotubes, the method comprising:
selecting an oligomer or polymer, wherein the oligomer or polymer is formed of repeat units, wherein each repeat unit has at least one charged functional group per 1-3 nm of oligomer or polymer length;
dispersing metallic single walled carbon nanotubes (SWNTs) in a suspension, the metallic SWNTs having a chiral index (n, m) where (n−m)/3 is an integer or 0; and
mixing an aqueous solution of the oligomer or polymer with the metallic SWNTs in the suspension to form superstructures having a desired band gap opening, each superstructure comprising a metallic SWNT of the metallic SWNTs and a conjugated oligomer or polymer of the selected oligomer or polymer that single-chain wraps about a surface of the metallic SWNT at fixed helical pitch length.

17. The method of claim 16, wherein the repeat units of the conjugated oligomer or polymer comprise a plurality of aryleneethynylene units in which the at least one charged functional group is incorporated at least once every 1-3 nm of oligomer or polymer length.

18. The method of claim 17, wherein each aryleneethynylene unit of the plurality of aryleneethynylene units contain 10 or fewer carbon fused aromatic ring systems.

19. The method of claim 16, wherein the repeat units of the conjugated oligomer or polymer possess a moiety that directs the conjugated oligomer or polymer to helically wrap the surface of the metallic SWNT in a left- or right-handed helical fashion.

20. The method of claim 19, wherein the repeat units feature a R- or S-binaphthalene (PBN)-based unit as the moiety that directs the conjugated oligomer or polymer to helically wrap the surface of the metallic SWNT in the left- or right-handed helical fashion.

21. The method of claim 20, wherein the oligomer or polymer is S-PBN-Ph₃, R-PBN-Ph₃, R-PBN-PZn₂, S-PBN(b)-Ph₅, S-PBN(b)-Ph₄PhCN, S-PBN(b)-Ph₂PZn₃, S-PBN(b)-Ph₂-PZnE-TDQ-EPZn, S-PBN(b)-Ph₂PZn₂, S-PBN-Ph₄PDI, or S-PBN(b)-Ph₄.

22. The method of claim 16, wherein the metallic SWNTs have a chiral index of (16,1), (16,4), (16,7), (16,10), (16,13), (16,16), (15,0), (15,3), (15,6), (15,9), (15,12), (15,15), (14,2), (14,5), (14,8), (14,11), (14,14), (13,1), (13,4), (13,7), (13,10), (13,13), (12,0), (12,3), (12,6), (12,9), (12,12), (11,2), (11,5), (11,8), (11,11), (10,1), (10,4), (10,7), (10,10), (9,0), (9,3), (9,6), (9,9), (8,2), (8,5), (8,8), (7,1), (7,4), (7,7), (6,0), (6,3), (6,6), (5,2), (5,5), (4,1), (4,4), (3,0), (3,3), (2,2), or (1,1).
